(19) United States
(12) Patent Application Publication
(10) Pub. No.: US 2024/0234391 A1
(43) Pub. Date: Jul. 11, 2024

(54) MICRO SYSTEM COMPRISING A PLURALITY OF FUNCTIONAL CELLS

(71) Applicant: ams-OSRAM International GmbH, Regensburg (DE)

(72) Inventor: Thomas SCHWARZ, Regensburg (DE)

(21) Appl. No.: 18/559,123

(22) PCT Filed: May 5, 2022
(86) PCT No.: PCT/EP2022/062172

§ 371 Date: Nov. 6, 2023

(30) Foreign Application Priority Data
May 7, 2021 (DE) 10 2021 112 018.7

(51) Int. Cl. H01L 25/16; H01L 25/18; H01L 31/05; H01L 33/48; H01L 33/62; H02S 40/38; H10N 39/00

(52) U.S. Cl. CPC H01L 25/16; H01L 25/167; H01L 25/18; H02S 40/38; H10N 39/00; H01L 31/0508; H01L 33/486; H01L 33/62

(57) ABSTRACT

A microsystem includes a plurality of functional cells at least partially electrically coupled to each other. Each functional cell is formed by one of the following cell types: electric energy generating cell; electric energy storing cell; electric energy conducting cell; and electric energy consuming cell. Each functional cell includes: a housing of an electrically insulating material, the housings of each two functional cells having the same dimensions; at least one first electrical connection area and at least one second electrical connection area; and a functional element arranged inside the housing with electrical connection of the at least one first electrical connection area and the at least one second electrical connection area.

The present application claims priority to German Patent Application No. 10 2021 112 018.7 dated May 7, 2021, the disclosure content of which is hereby incorporated by reference into the present application.

The present invention relates to functional cells, a microsystem comprising a plurality of functional cells, a method of manufacturing functional cells, and a method of manufacturing a microsystem comprising a plurality of functional cells.

Bionics deals with the transfer of phenomena from nature to technology. In many technical areas, it has already been possible to transfer phenomena from nature to technology. However, in the field of autonomous microsystems, such as microrobots with the size of small insects or worms, hardly any solutions are known at this time to provide such a system based on phenomena from nature.

Existing microsystems are miniaturized devices, assemblies or a component whose components have the smallest dimensions in the range of 1 micrometer and interact as a system. Existing microsystems can, for example, consist of one or more sensors, actuators and control electronics arranged on a carrier or chip. At present, such microsystems are usually limited to relatively large assemblies with dimensions of several millimeters due to their design, manufacture and the components used. In addition, the production of such microsystems is currently very cost-intensive, as they have to be manufactured individually and using non-standardized processes.

Therefore, there is a need to counteract the aforementioned problems and provide a microsystem and a method for manufacturing a microsystem that is easy to manufacture and has small dimensions.

### SUMMARY OF THE INVENTION

This need is addressed by a functional cell having the features of independent claim 1, by a microsystem comprising a plurality of functional cells having the features of independent claim 19, by a method of making a functional cell having the features of independent claim 29, and by a method of making a microsystem having the features of independent claim 33. Embodiments and further embodiments of the invention are described in the de-pendent claims.

The inventor has made use of a phenomenon found in nature by creating an autonomous microsystem consisting of a large number of cells that are interconnected and interact with each other. The cells can be the same size as biological cells, but with a much simpler structure, and depending on the type of cell, can perform different functions within the microsystem. In the following, such cells are therefore called functional cells. In contrast to biological cells, functional cells do not have an intrinsic blueprint, they cannot self-replicate, and they cannot obtain their energy via a complicated biochemical metabolic process. However, functional cells can be of different types and can be of a different cell type, such as electrical energy generating cells, electrical energy storing cells, electrical energy conducting cells, and electrical energy consuming cells. A common feature of the functional cells is that they each have a housing with the same dimensions. This makes it possible, depending on the application, to easily combine the various individual cells in any order and in any composition to form a microsystem. The resulting possibilities and freedom in the arrangement of the functional cells in relation to each other make a high degree of standardization in the manufacturing process conceivable, since the functional cells can be provided in large quantities and these can be individualized and easily combined according to the desired application.

A functional cell according to the invention has a cell type, wherein the cell type forms a cell type consisting of the following types:
electrical energy generating cell;
electrical energy storing cell;
electrical energy conducting cell;
electrical energy consuming cell;

Further, the functional cell comprises a housing made of an electrically insulating material and the housing of each two types of cells has the same dimensions. The functional cell comprises at least one first electrical connection area and at least one second electrical connection area, wherein the at least one first electrical connection area and the at least one second electrical connection area are arranged on two opposite outer surfaces of the housing. In addition thereto, the functional cell comprises a functional element associated with the respective cell type and/or identifying the cell type and arranged inside the housing with electrical connection of the at least one first electrical connection area and the at least one second electrical connection area.

The housing of the functional cells may in particular be formed by a base layer and a cover layer, which span a cavity or hollow between the two layers. The functional element of the functional cells may be arranged in this cavity or hollow space, and the functional element may in particular fill this cavity or hollow space.

The housing can form the cell body of the functional cell, following the example of a biological cell. In particular, the housing or the cell body can consist of or comprise an electrically insulating material or a non-conductive material, so that the housing or the cell body is electrically non-conductive on its outer surfaces. The only exception to this can be the electrical connection areas that are arranged on the outer surfaces of the housing or protrude from them.

In some embodiments, the functional element comprises at least one of the following:
an electrical conductor in the case of the cell type being of an electrical energy conducting cell;
a photocell in the case of the cell type being of an electric energy generating cell;
a solar cell, in particular μ-solar cell, in the case of the cell type being of an electric energy generating cell;
a fuel cell, in particular a μ-fuel cell, in the case of the cell type being of an electrical energy generating cell;
a piezoelectric element in the case of the cell type being of an electric energy generating cell or in the case of the cell type being of an electric energy consuming cell;
an accumulator, in particular a μ-accumulator, in the case of the cell type being an electric energy storing cell;
a capacitor in the case of the cell type being an electric energy storing cell;
an optoelectronic semiconductor component, in particular an LED or μ-LED or a sensor or μ-sensor in the case of the cell type being of an electrical energy consuming cell;
an artificial neuron in the case of the cell type being of an electrical energy consuming cell;
an integrated circuit, in particular μ-IC, in the case of the cell type being of an electric energy consuming cell; and
a heating wire and optionally additionally a liquid, in particular oil, surrounding the heating wire and introduced into the housing, in the case of the cell type being of an electrical energy consuming cell.

In particular, the functional element may be formed by an energy generating element in the cell type of an electric energy generating cell, by an energy storing element in the cell type of an electric energy storing cell, by an energy conducting element in the cell type of an electric energy conducting cell, by an actuator in the cell type of an electric energy consuming cell, by a controller in the cell type of an electric energy consuming cell, or by an optoelectronic semiconductor device such as an LED or a sensor in the cell type of an electric energy consuming cell.

For example, a functional cell of the cell type of an electric energy generating cell can convert ambient light, or a fuel carried or supplied by the cell, into electric energy. The energy generated by the functional cells of the cell type of an electric energy generating cell can be stored in cells of the cell type of an electric energy storing cell, or such cells can be externally supplied or charged with electric energy. Cells of cell type of electric energy consuming cell may perform controlling functions, or such cells may perform movement, heating, light emission, or light detection in the form of actuators, or optoelectronic devices. Cells of the cell type of an electric energy conducting cell can conduct electric energy between the mentioned cell types.

The functional element may comprise, for example, an artificial neuron in the cell type of an electrical energy consuming cell. Such an artificial neuron may be modeled on a natural neuron and may, for example, be in the form of a logic gate (AND, OR, XOR, . . . ) or in the form of an integrated circuit (IC) or contain such an element.

In some embodiments, the functional element does not exceed a size of 100 μm×100 μm×100 μm. In particular, the functional elements within this application are declared u, such as μ-LED, μ-IC, μ-solar cell, or μ-accumulator, to express that they are very small elements, in particular elements with a size smaller than 100 μm×100 μm×100 μm.

In some embodiments, the functional cell housing does not exceed a size of 500 μm×500 μm×500 μm, or 250 μm×250 μm×250 μm, or 100 μm×100 μm×100 μm. In particular, the housing of each two cell types, and in particular of all cell types, has the same dimensions. In some embodiments, the housing of each two cell types and in particular of all cell types has the same dimensions and the same shape. This has the advantage that the functional cells can be stacked and combined in a space-saving manner and in any order and composition.

In some embodiments, the housing comprises an electrically insulating material or the housing comprises an electrically insulating material. For example, the housing comprises at least one of epoxy resin, silicone, acrylate, polyethylene terephthalate (PET), polyethylene (PE), a thermoplastic, a thermoset, Al₂O₃, AlN, glass, and ceramic.

In some embodiments, the at least one first electrical connection area and the at least one second electrical connection area are each formed by a leaf spring projecting from the housing or from an outer surface of the housing. For example, the at least one first electrical connection area and the at least one second electrical connection area may each be formed similarly to a through contact in an electrical switch.

In some embodiments, the at least one first electrical terminal area and the at least one second electrical terminal area have a coating of gold or other low oxidation material, or the at least one first electrical terminal area and the at least one second electrical terminal area have a coating of a solder compound. In some embodiments, the at least one first electrical connection area and the at least one second electrical connection area each have a roughened or spiked surface at least in the regions outside the housing. This may, for example, provide better electrical contact between multiple functional cells.

In some embodiments, the at least one first electrical connection area and the at least one second electrical connection area are each formed by or include a contact pad formed on two opposing outer surfaces of the housing.

In some embodiments, the at least one first electrical connection area and the at least one second electrical connection area each have a solder bump arranged on the housing or contact pad. A solder wetting area on the housing may be smaller than the solder bump arranged on the housing in each case in the area of a solder bump. In particular, a solder wetting area may be limited to a contact pad disposed on the housing, and a solder bump disposed on the contact pad may cover a larger area than the area of the contact pad or solder wetting area. For example, the solder wetting area may be limited by a solder bump applied to the package. In the event that the functional cell or the at least one first electrical connection area and the at least one second electrical connection area are heated, the respective solder bump retracts to the area of the solder wetting surface.

In some embodiments, the functional cell further comprises at least one third electrical connection area and at least one fourth electrical connection area, wherein the at least one third electrical connection area and the at least one fourth electrical connection area are disposed on two opposing exterior surfaces of the housing.

In some embodiments, the functional cell further comprises at least one fifth electrical connection area and at least one sixth electrical connection area, wherein the at least one fifth electrical connection area and the at least one sixth electrical connection area are disposed on two opposing exterior surfaces of the housing.

In some embodiments, at most one of the at least one first, second, third, fourth, fifth, and sixth electrical connection areas is disposed on each exterior surface of the housing.

In some embodiments, exactly one of the at least one first, second, third, fourth, fifth and sixth electrical connection areas is arranged on each outer surface of the housing. Accordingly, in the case of a cuboid or cube-shaped housing with six outer surfaces, exactly one electrical connection area, for a total of six electrical connection areas, may be arranged on each of the outer surfaces.

In some embodiments, the functional cell further comprises at least one seventh electrical connection area, wherein the at least one seventh electrical connection area is disposed on an outer surface of the housing. In contrast to aforementioned electrical connection areas, the seventh electrical connection area may be disposed on an outer surface of the housing without another electrical connection area associated with the seventh electrical connection area being disposed on the opposite outer surface of the housing.

In some embodiments, at least two of the at least one first, third, fifth, and seventh, or the at least one second, fourth, sixth, and seventh electrical connection areas are disposed on at least one exterior surface of the housing.

The number of electrical connection areas on an outer surface of the housing can be selected variably and adapted to the requirements of the functional cell. However, in order to be able to provide a high degree of standardization in the manufacturing process of the functional cells and versatile combination options for the functional cells, it can be advantageous that at most one electrical connection area is arranged on each outer surface of the housing.

In some embodiments, the electrical connection areas comprise or consist at least in part of any of the following materials: copper, nickel, gold, silver, indium, tin, and bismuth.

In case the functional cell is of the cell type of an electric energy conducting cell, and the functional element comprises at least one electric conductor, the electric conductor may electrically interconnect the at least one first and/or the at least one second and/or the at least one third and/or the at least one fourth and/or the at least one fifth and/or the at least one sixth and/or the at least one seventh electric terminal area. In addition thereto, at least one further electrical conductor may electrically interconnect at least a part of the remaining electrical connection areas not yet interconnected. Possible combinations and specific examples regarding possible electrical connections between the electrical connection areas are explained below in the detailed description or figure description using a short circuit table.

In some embodiments, the housing is rotationally symmetric along at least one axis or is mirror symmetric along at least one plane. In some embodiments, the housing is rotationally symmetric along multiple axes or mirror symmetric along multiple planes. High symmetry of the housing can provide high standardization in the manufacturing process of the functional cells and versatile combination options of the functional cells. Furthermore, high symmetry of the housing may be advantageous because the orientation of the housing may play little or no role in the assembly of multiple functional cells.

In some embodiments, the enclosure comprises one of the following shapes: Cube, in particular a cube with rounded edges; Cuboid, in particular a cuboid with rounded edges; Beam, in particular a beam with rounded edges; Sphere; Ellipsoid; Pyramid, in particular a pyramid with rounded edges; Truncated pyramid, in particular a truncated pyramid with rounded edges; and Truncated cone, in particular a truncated cone with rounded edges.

Rounded or rounded edges or corners of the housing shape can serve in particular to reduce the stresses in the housing or in the composite of the cells as a microsystem. Further, the shape of the cell may affect the expansion of the cell in the event that the cell includes an actuator, in the case of the cell type of an electrical energy consuming cell. For example, an enclosure in the shape of a sphere may expand substantially isotropically in the event of an increase in temperature, whereas an enclosure in the shape of a cuboid, or a bar or rod, may expand substantially anisotropically. Such a varying expansion of the cell may be desired, for example, if the composite of cells as a microsystem is to perform a particular movement.

In some embodiments, the functional cell comprises an adhesive layer covering at least one outer surface of the housing. In particular, the adhesive layer covers the at least one outer surface of the housing such that any electrical connection area or electrical connection areas disposed on the outer surface of the housing are not covered by the adhesive layer. The adhesive layer may be used, for example, to interconnect a plurality of functional cells.

A microsystem according to the invention comprises a plurality of functional cells that are at least partially electrically coupled to each other. The functional cells each have a cell type, wherein the cell type forms a cell type consisting of the following types:
electrical energy generating cell;
electrical energy storing cell;
electrical energy conducting cell;
electrical energy consuming cell;

Each functional cell comprises a housing made of an electrically insulating material, wherein the housings of each two functional cells have the same dimensions. Further, each functional cell comprises at least one first electrical connection area and at least one second electrical connection area and a functional element arranged inside the housing with electrical connection of the at least one first electrical connection area and the at least one second electrical connection area.

In particular, the functional cells of the microsystem may be formed according to the embodiments of the functional cells described in the above.

That the functional cells are at least partially electrically coupled to each other means that at least a portion of the plurality of functional cells are electrically coupled to each other, however, the microsystem may also have cells that are not electrically coupled to any other cell of the microsystem. However, all cells of the microsystem may be at least mechanically coupled to each other.

In some embodiments, the plurality of functional cells are arranged side-by-side in a first plane, resulting in a layer of functional cells arranged side-by-side. However, in some embodiments, a first subset of the plurality of functional cells may be arranged side-by-side in a first plane, and a second subset of the plurality of functional cells may be arranged in a second plane parallel to the first plane. Thus, the cells may be arranged in two or more superimposed layers. The layers of cells or the planes in which the subsets of cells are arranged can either comprise the same number of cells, but the number of cells in the layers or in the planes can also differ. In particular, the area or space occupied by the cells per layer or per level may also differ. Due to the multiple layers, each with a different number of cells arranged therein, the microsystem can be formed in all conceivable volume freeforms or in the form of a fabric in space. Within this free form or within this fabric, existing and opposing electrical connection areas of the individual cells can be electrically coupled to each other.

In some embodiments, the microsystem comprises at least one non-electric cell, wherein a housing of the at least one non-electric cell has substantially the same dimensions and, in particular, the same shape as a housing of a functional cell.

For example, the housing of the at least one non-electric cell may be formed by a substantially transparent material.

For example, one such non-electric cell or a plurality of such non-electric cells may form a spacer between functional cells, a light guide between functional cells, an elastomer between functional cells, or an outer armor or protective shell for the microsystem. Similarly, it is possible, for example, for a plurality of such non-electric cells to form a cavity for a fuel to power an electric energy generating cell.

The housing of the at least one non-electric cell may be formed by, for example, or comprise at least one of the following materials: Epoxy resin, silicone, acrylate, polyethylene terephthalate (PET), polyethylene (PE), a thermoplastic, a thermoset, Al₂O₃, AlN, glass, and ceramic. In particular, the housing of the at least one non-electric cell may be formed of a hard, transparent material, such as an epoxy resin, and have a comparatively softer core of, for example, silicone.

In some embodiments, the functional cells and the non-electrical cells are encapsulated in an interconnect layer. In particular, the interconnect layer may provide a mechanical connection between the cells or at least provide a mechanical connection between the cells that are not coupled via the electrical pads. The interconnect layer may further have insulating properties to prevent unwanted short circuits or unwanted contacting within the microsystem.

In some embodiments, the interconnect layer is formed of an electrically insulating material and comprises or consists particularly of one of the following materials: a synthetically produced hydrocarbon, particularly forming a polymer, plastic, silicone, acrylate, epoxy resin, PET, PE, a thermoplastic, a thermoset, and an elastomer.

In some embodiments, a subset of the plurality of functional cells arranged adjacent to each other has the same cell type. In particular, a subset of the plurality of functional cells arranged adjacent to each other and in electrical communication with each other has the same cell type. Accordingly, the microsystem has sub-regions, the sub-regions being characterized in that the cells therein have the same cell type, are arranged adjacent to each other, and are optionally in electrical communication with each other.

In some embodiments, the at least one first electrical connection area and the at least one second electrical connection area of each functional cell are formed by a leaf spring projecting from the housing of the respective functional cell. Opposing leaf springs of two adjacent functional cells may thereby be in electrically conductive connection with each other. The electrically conductive connection can be created in particular by the leaf springs touching or resting on each other. In particular, the electrically conductive connection can result from the leaf springs being pressed against each other and slightly bent, thus exerting a force on the leaf springs which in turn generates a contact force.

The bending of the leaf springs can result from a force applied to the functional cells during the manufacturing process, for example by pressing the functional cells together, or the bending can result from the compound layer applied for casting the cells hardening and contracting. The shrinkage of the material of the compound layer can cause the functional cells to be closer together after curing, resulting in a force on the leaf springs.

In addition, or alternatively, the leaf springs or the electrical connection areas can comprise a coating of a solder com-pound, so that the electrically conductive connection can be created by soldering the opposing leaf springs or electrical connection areas to one another at least in the area of the coating. The soldering can be carried out in particular by pressing the opposing leaf springs or electrical connection areas onto one another and simultaneously heating them.

In some embodiments, the at least one first electrical connection area and the at least one second electrical connection area of each functional cell are formed with solder bumps. Opposite solder bumps of two adjacent functional cells may be soldered together and thus be in electrically conductive connection with each other. In particular, the at least one first electrical connection area and the at least one second electrical connection area of each cell can each be formed by or have a contact pad. A solder bump may be disposed on each of the contact pads. A solder wetting area on the housing of each cell can thereby be smaller in each case in the area of the solder bumps than the solder bump arranged on the housing. In particular, the solder wetting area may be limited to the contact pads arranged on the housing, and the solder bump applied to each of the contact pads may cover a larger area than the area of the contact pad or the solder wetting area. When the functional cells are electrically connected, they or at least the opposing electrical connection areas of the functional cells can be heated so that the respective solder bump retracts to the area of the solder wetting surface and the opposing solder bumps “grow together” or are soldered.

In some embodiments, the microsystem further comprises another functional cell having a housing having dimensions substantially equal to a multiple of the dimensions of a housing of one of the plurality of functional cells. In this regard, the further functional cell may have a cell type, wherein the cell type forms a cell type consisting of the following types:
electrical energy generating cell;
electrical energy storing cell;
electrical energy conducting cell;
electrical energy consuming cell.

In particular, the further functional cell may be formed in accordance with the embodiments of the functional cell described in the above, but may have dimensions that are substantially a multiple of the dimensions of a housing of the embodiments of the functional cell described in the above.

By the further functional cell or the housing of the further functional cell having dimensions substantially corresponding to a multiple of the dimensions of a housing of the embodiments of the functional cell described in the above, it is possible to arrange the further functional cell in the microsystem instead of a number of smaller cells described in the above.

Such a larger further functional cell may be particularly advantageous if the microsystem requires increased computing power or control. Thus, it may be useful to have a larger integrated circuit (IC) in a functional cell as opposed to multiple small integrated circuits in multiple smaller functional cells. Another application of a larger cell could be when a lens, for example, is to be provided by a larger non-electric cell, which might not be feasible with multiple smaller non-electric cells.

A method according to the invention for producing a functional cell of a cell type, wherein the cell type forms a cell type consisting of the following types:
electrical energy generating cell;
electrical energy storing cell;
electrical energy conducting cell;
electrical energy consuming cell;
   comprises the following steps:
Providing a carrier with a release layer thereon;
Application of a base layer on top of the release layer;
Structuring the base layer to create at least one cavity or at least one hollow;
Placing a functional element associated with the respective cell type and/or identifying the cell type in the at least one cavity or the at least one hollow space;
applying an electrically conductive structure to create at least a first electrical connection area and at least a second electrical connection area; and
Applying a cover layer to encase the functional element.

In particular, the method of manufacturing a functional cell may be adapted to form the functional cells of the microsystem according to the embodiments of the functional cell described in the above.

The process according to the invention may comprise steps known from thin film technology such as physical vapor deposition (PVD), chemical vapor deposition (CVD), lithography, and etching. Further, the process may also include steps known from printing technology such as stereo lithography, jet printing, screen printing, stencil printing, and offset printing. For example, the step of patterning the base layer may be performed by a photolithography process or a wet chemical etching process, and the step of applying an electrically conductive pattern may be performed, for example, by vapor deposition and sputtering of an electrically conductive material followed by lift-off processes or etching techniques.

In some embodiments, the functional element disposed in the at least one cavity or hollow comprises at least one of the following:
an electrical conductor in the case of the cell type being of an electrical energy conducting cell;
a photocell in the case of the cell type being of an electric energy generating cell;
a solar cell, in particular μ-solar cell, in the case of the cell type being of an electric energy generating cell;
a fuel cell, in particular a μ-fuel cell, in the case of the cell type being of an electrical energy generating cell;
a piezoelectric element in the case of the cell type being of an electric energy generating cell or in the case of the cell type being of an electric energy consuming cell;
an accumulator, in particular a μ-accumulator, in the case of the cell type being an electric energy storing cell;
a capacitor in the case of the cell type being an electric energy storing cell;
an optoelectronic semiconductor component, in particular an LED or μ-LED or a sensor or μ-sensor in the case of the cell type being of an electrical energy consuming cell;
an artificial neuron in the case of the cell type being of an electrical energy consuming cell;
an integrated circuit, in particular μ-IC, in the case of the cell type being of an electric energy consuming cell; and
a heating wire and optionally additionally a liquid, in particular oil, surrounding the heating wire and introduced into the housing, in the case of the cell type being of an electrical energy consuming cell.

In some embodiments, the method further comprises a step of structuring the base layer and/or the cover layer and/or the electrically conductive structure. By this step, a plurality of functional cells formed on the release layer may be separated from each other so that they subsequently yield individual components. Accordingly, this step may also be referred to as the separation step.

In some embodiments, the step of applying an electrically conductive structure comprises:
creating an electrical connection area;
an application of a solder stop around the connection area; and
an application of a solder bump to the electrical connection area.

However, the latter two steps can also be performed downstream, after the step of applying a cover layer to encapsulate the functional element.

A method of manufacturing a microsystem according to the invention comprising a plurality of functional cells at least partially electrically coupled to each other, wherein each functional cell is formed by one of the following cell types:
electrical energy generating cell;
electrical energy storing cell;
electrical energy conducting cell; and
electrical energy consuming cell;
   comprising the steps:
Providing a carrier with an adhesive layer thereon;
Arranging a subcarrier structure above the adhesive layer, the subcarrier structure comprising a plurality of regions each populated with different cell types of the functional cells;
irradiating a first functional cell in a first region of the subcarrier structure such that the functional cell detaches and falls onto the adhesive layer; and
irradiating another functional cell in a second region of the subcarrier structure such that the functional cell detaches and falls onto the adhesive layer adjacent to the first cell.

In particular, the method of manufacturing a microsystem comprising a plurality of functional cells may be adapted to form the microsystem according to the embodiments described above.

The method according to the invention can comprise steps which are known from a laser lift off method.

By means of the method, a plurality of functional cells may be juxtaposed in a first plane, resulting in a layer of juxtaposed functional cells. However, in some embodiments, a first subset of the plurality of functional cells may be arranged side-by-side in a first plane, and a second subset of the plurality of functional cells may be arranged in a second plane parallel to the first plane. Thus, the cells may be arranged in two or more superimposed layers. The layers of cells or the planes in which the subsets of cells are arranged can either comprise the same number of cells, but the number of cells in the layers or in the planes can also differ. In particular, the area or space occupied by the cells per layer or per level may also differ. Accordingly, several layers can be formed by the process, whereby the several layers can be formed with a different number of cells arranged therein in all conceivable volume free forms or in the form of a fabric in space. Within this free form or within this fabric, existing and opposing electrical connection areas of the individual cells can be electrically coupled to one another.

In some embodiments, the method further comprises a step of potting the functional cells arranged on the carrier. In particular, it may be provided that a layer of functional cells is formed by means of the method, this layer is potted and subsequently further functional cells are arranged in a plane parallel to the first layer. The resulting further layer can then be cast again before a new third layer parallel to the first or second layer is created.

### BRIEF DESCRIPTION OF THE DRAWINGS

In the following, embodiments of the invention are explained in more detail with reference to the accompanying drawings. They show, schematically in each case,

FIGS. 1A and 1B a front view and a top view of a functional cell according to some aspects of the proposed principle;

FIG. 2 a microsystem comprising a plurality of functional cells according to some aspects of the proposed principle;

FIGS. 3A to 3E different cell types of a functional cell, and a non-electric cell is formed according to some aspects of the proposed principle;

FIGS. 4A and 4B another embodiment of a functional cell and a microsystem comprising a plurality of functional cells according to some aspects of the proposed principle;

FIGS. 5A to 5C further embodiments of a functional cell and a microsystem comprising a plurality of functional cells according to some aspects of the proposed principle;

FIGS. 6A to 8B front and top views of further embodiments of a functional cell according to some aspects of the proposed principle;

FIGS. 9A to 9H housing shapes for a functional cell according to some aspects of the proposed principle;

FIG. 10 another embodiment of a microsystem comprising a plurality of functional cells according to some aspects of the proposed principle;

FIGS. 11 and 12 further embodiments of a microsystem comprising a plurality of functional cells according to some aspects of the proposed principle;

FIG. 13 steps of a method for manufacturing a functional cell according to some aspects of the proposed principle; and

FIG. 14 steps of a method for manufacturing a microsystem comprising a plurality of functional cells according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size to highlight individual aspects. It will be understood that the individual aspects and features of the embodiments and examples shown in the figures may be readily combined without affecting the principle of the invention. Some aspects have a regular structure or shape. It should be noted that minor deviations from the ideal shape may occur in practice, but without contradicting the inventive idea.

In addition, the individual figures, features and aspects are not necessarily shown in the correct size, nor do the proportions between the individual elements have to be fundamentally correct. Some aspects and features are highlighted by showing them enlarged. However, terms such as “above”, “above”, “below”, “below”, “larger”, “smaller” and the like are correctly represented in relation to the elements in the figures. Thus, it is possible to derive such relationships between the elements based on the figures.

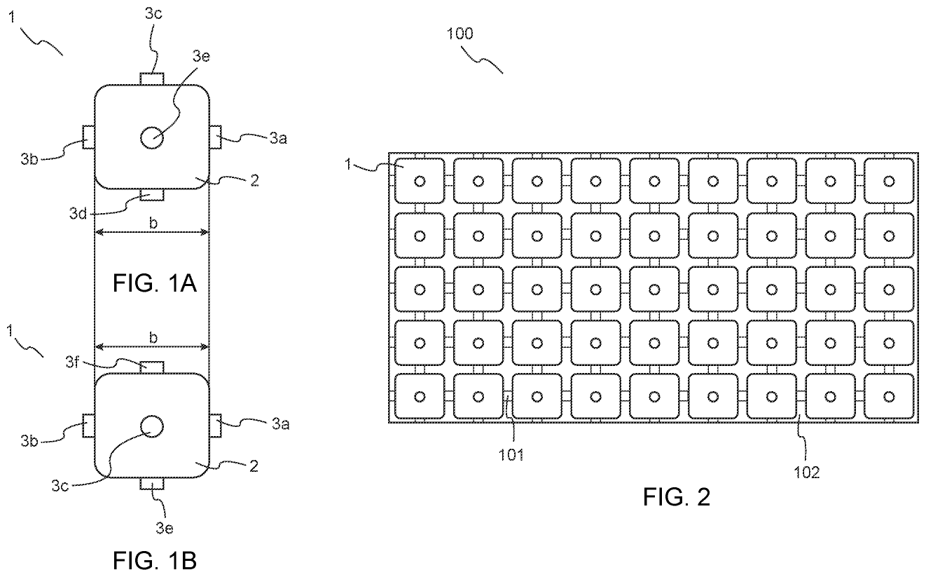

FIGS. 1A and 1B show a front view and a top view of a functional cell 1. The functional cell 1 includes a housing 2, and a first electrical connection area 3a, a second electrical connection area 3b, a third electrical connection area 3c, a fourth electrical connection area 3d, a fifth electrical connection area 3e, and a sixth electrical connection area 3f. The housing 2 has a shape of a cube and the terminal areas 3a, 3b, 3c, 3d, 3e, 3f are each arranged on an outer side of the housing 2. The first and the second electrical connection areas 3a, 3b, the third and the fourth electrical connection areas 3c, 3d and the fifth and the sixth electrical connection areas 3e, 3f are furthermore each arranged on two opposing outer surfaces of the housing, so that exactly one of the connection areas is arranged on each outer surface. The dimensions of the housing, in particular the height, depth or width b of the housing, are very small, in particular the width b and thus also the height and depth of the housing can have a value between 10 μm and 100 μm.

The functional cell 1 further comprises a functional element not explicitly shown here, which is arranged inside the housing 2 with electrical connection of at least two of the electrical connection areas. Each functional cell is associated with a functional element by means of which a cell type can be assigned to the cell or by means of which the cell type of the functional cell can be identified. Thus, the functional cell can have different functions according to the functional element arranged inside its housing, which can be combined within a microsystem.

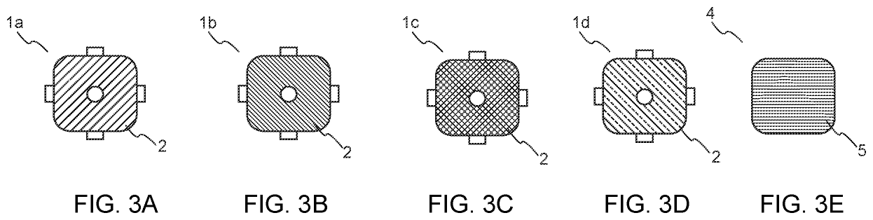

FIG. 2 shows a microsystem 100 comprising a plurality of functional cells 1, the functional cells 1 being formed according to the functional cells 1 shown in FIGS. 1A and 1B. The functional cells 1 are respectively arranged adjacent to each other in the form of a tissue, and opposing electrical connection areas of two adjacent functional cells are electrically connected to each other to form an electrical connection 101. The functional cells 1 may be arranged in one or more layers, so that the microsystem 100 may also have further layers of functional cells into the drawing plane or out of the drawing plane to form a solid body. The layers of cells may each comprise the same number of cells, but the number of cells within the layers may also differ. In particular, the area or space occupied by the cells per layer may also differ as a result. By having layers, each with a different number of cells arranged therein, the microsystem can be formed in all conceivable volume freeforms. Within this free form or within this fabric, the existing and opposing electrical connection areas of the individual cells can be electrically connected to each other.

The functional cells 1 are further encapsulated in an interconnect layer 102 or with a potting material to provide an additional mechanical connection between the functional cells. The interconnect layer 102 may further have insulating properties to prevent unwanted short circuits or unwanted contacting within the microsystem 100.

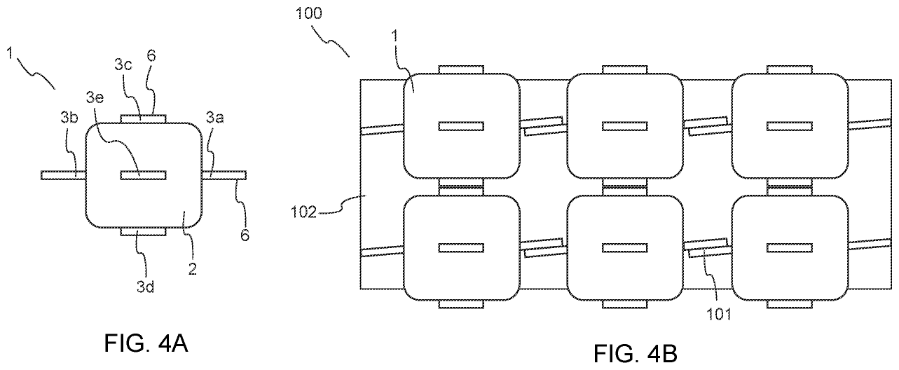

FIG. 3A to 3D show different cell types of a functional cell. The functional cells 1a, 1b, 1c, 1d of different cell types differ in particular by different (not shown) functional elements arranged inside the housing 2 of a functional cell. FIG. 3A shows a functional cell 1a of the cell type of an electric power generating cell. Such a cell may comprise as a functional element, for example, a photocell, a solar cell, a fuel cell, or a piezoelectric element, and may in particular be designed to generate electrical energy. FIG. 3B shows a functional cell 1b of the cell type of an electric energy conducting cell. Such a cell can comprise, for example, one or more electrical conductors as a functional element and, in particular, be designed to conduct electrical energy with as little loss as possible. FIG. 3C shows a functional cell 1c of the cell type of an electrical energy consuming cell. Such a cell may comprise as a functional element, for example, a piezoelectric element, an optoelectronic semiconductor device, in particular an LED or μ-LED or a sensor or μ-sensor, an artificial neuron, an integrated circuit, or a heating wire and optionally additionally a liquid, in particular oil, surrounding the heating wire and introduced into the housing. The functional cell 1c of the cell type of an electrical energy consuming cell can in particular be designed to generate a movement in the form of an actuator, to emit light or to serve as a controller for a microsystem. FIG. 3D shows a functional cell 1d of the cell type of an electrical energy storing cell. Such a cell can comprise, for example, an accumulator or capacitor as a functional element and, in particular, be designed to store electrical energy.

FIG. 3E shows a non-electric cell 4. The non-electric cell 4 has a housing 5 that has the same dimensions and shape as the housing of the functional cells in FIGS. 3A to 3D. Such a non-electric cell 4 or a plurality of such non-electric cells may, for example, form a spacer between functional cells, a light guide between functional cells, an elastic connection between functional cells, or an outer armor or protective shell for a microsystem. Similarly, it is possible, for example, for a plurality of such non-electric cells 4 to form a cavity for a fuel to power an electric power generating cell.

In contrast to a functional cell, the non-electric cell 4 has no functional element in its interior and also no electrical connection areas. However, in areas where the functional cells have the electrical connection areas, the non-electric cell 4 can have webs arranged on the housing sides that can be connected at least mechanically to the electrical connection areas of the functional cells.

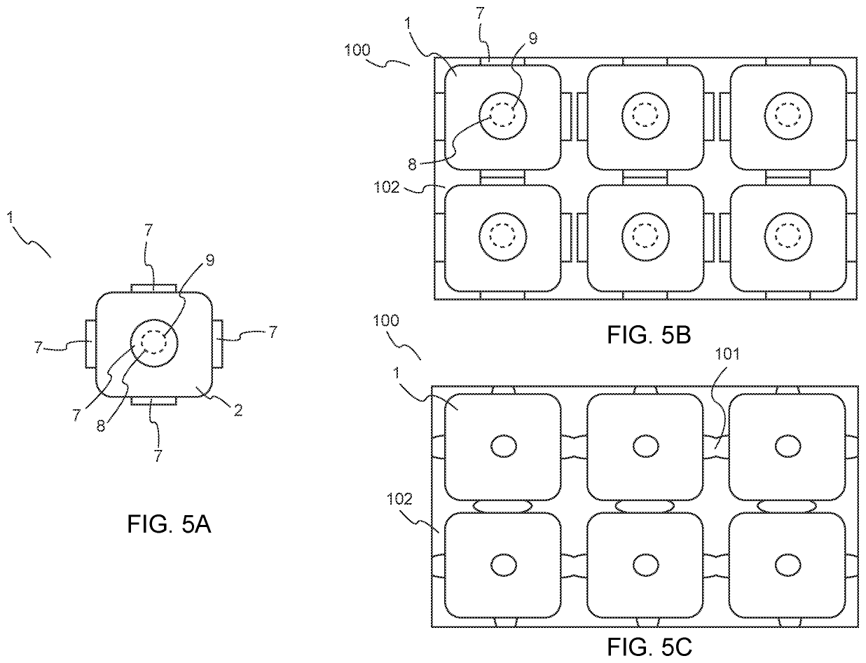

FIG. 4A shows a side view of an embodiment of a functional cell. The functional cell is formed according to one of the functional cells shown in FIGS. 3A to 3D. However, the electrical connection areas 3a, 3b, 3e, 3f on the lateral outer surfaces of the housing 2 are formed in the form of leaf springs in the illustrated case, and the electrical connection areas 3c, 3d on the upper and lower outer surfaces of the housing 2 are formed in the form of contact pads. Each of the leaf springs protrudes in a vertical direction from the lateral outer surfaces of the housing 2. Both the leaf springs and the contact pads have a coating 6. The coating 6 may, for example, be made of or comprise a gold or other oxidation-resistant material, or the coating 6 may comprise or comprise a solder compound. Additionally, or alternatively, it is possible for both the leaf springs and the contact pads to have a roughened or spiked surface at least in the regions outside the housing 2. This may, for example, provide better electrical contact between a plurality of functional cells 1.

FIG. 4B shows a microsystem 100 comprising a plurality of the functional cells 1 of FIG. 4A. The functional cells 1 are arranged side-by-side and on top of each other, and opposing leaf springs or contact pads of the functional cells 1 are in electrical communication 101 with each other. The functional cells 1 are further encapsulated in an interconnect layer 102 to provide additional mechanical stability to the microsystem 100.

A contact force between the opposing leaf springs or contact pads is achieved by arranging the functional cells 1 next to and on top of each other, then casting them in the interconnect layer, and the curing of the interconnect layer, i.e. the shrinkage in the interconnect layer, produces a contact force that acts on the leaf springs or contact pads. In addition, an increased contact force acts between the leaf springs due to the fact that the leaf springs in the illustrated arrangement are bent slightly upwards or slightly downwards and are thus under tension. As a result, two opposing spring forces act on the contact points between the leaf springs.

Before and during the curing of the interconnect layer 101, an additional force can be applied to the functional cells 1 so that the interconnect layer cures in a state in which the electrical connection areas are optimally in electrical connection with each other.

In the case that the coating 6 on the leaf springs or the contact pads contains or consists of a solder connection, the microsystem 100 or at least the electrical connection areas can be additionally heated so that an electrical connection 101 between the functional cells 1 results not only due to a contact force but also due to an intermetallic connection between the electrical connection areas.

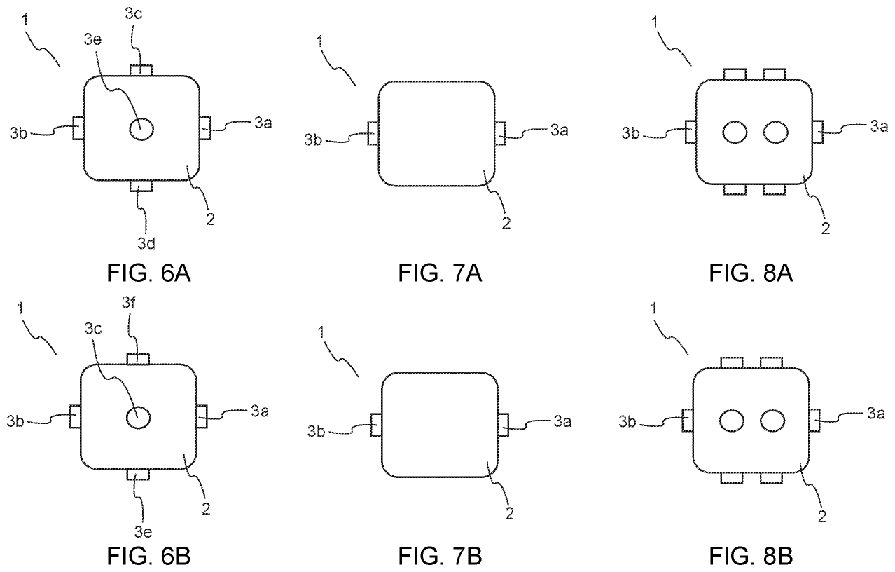

FIG. 5A shows a side view of a further embodiment of a functional cell 1. The functional cell 1 is designed according to one of the functional cells shown in FIGS. 3A to 3D. However, in the case shown, the electrical connection areas on the outer sur-faces of the housing 2 have solder bumps 7. Below the solder bumps 7, the electrical connection areas each comprise a contact pad 8. A solder bump 7 is arranged on each of the contact pads 8. In addition, the electrical connection areas are designed in such a way that a solder wetting area 9 is limited only to the area of the contact pads 8. The solder bumps 7, which are each applied to the contact pads, therefore cover a larger area than the area of the contact pad 8 or the area of the solder wetting surface 9. When the electrical connection areas are heated, and in particular when the solder bumps 7 are heated, the solder material of the solder bumps retracts to the area of the solder wetting surface 9, so that the solder material of the solder bumps 7 is arranged only in the area of the contact pads 8.

FIG. 5B shows a microsystem 100 comprising a plurality of the functional cells 1 of FIG. 5A, but which are not yet, only partially, or insufficiently electrically connected to each other. The functional cells 1 are arranged side by side and on top of each other, and solder bumps of opposing functional cells 1 are also facing each other or slightly touching each other. The functional cells 1 are further encapsulated in a interconnect layer 102 to provide additional mechanical stability to the microsystem 100.

By selectively heating the solder bumps 7 or the electrical connection areas, or by heating the entire microsystem 100 of FIG. 5B, the opposing solder bumps 7 of two adjacent functional cells 1 are soldered together so that they are in electrically conductive connection 101 with each other. The resulting assembly is shown in FIG. 5C. As the microsystem 100 is heated, or as the electrical connection areas or solder bumps 7 are heated, the material of the solder bumps retracts to the region of the solder wetting surface 9 and “grows” upward perpendicular to the solder wetting surface 9. This process bridges a gap between opposing solder bumps 7, and the opposing electrical connection surfaces “grow” together or are soldered together. The material of the interconnect layer 102 is displaced by such a soldering process in the areas between opposing electrical connection areas, and the solder connection grows through the material of the interconnect layer 102, so to speak. For this purpose, the interconnect layer 102 may contain, for example, a flux.

However, such a soldering process can also be carried out before the functional cells 1 are potted in the interconnect layer 102. In such a case, the solder joint does not have to grow through the material of the interconnect layer 102, but the soldering process is carried out in an upstream step.

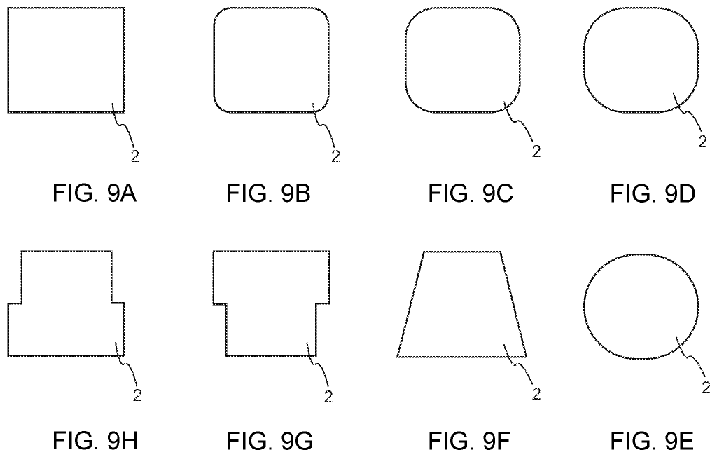

In the case that the functional cell 1 is of the cell type of an electric energy conducting cell as shown in FIGS. 6A and 6B, and the functional element thus comprises at least one electric conductor, an electric conductor can electrically connect the electric connection areas or at least some of the electric connection areas 3a, 3b, 3c, 3d, 3e, 3f to each other as desired. Some possible combinations or specific examples regarding possible electrical connections between the electrical connection areas are shown in the following short circuit table Table 1.

TABLE 1
Short circuit table for functional cell
of electric energy conducting cell type

| | el. Connection area | | | | | | |
|---|---|---|---|---|---|---|---|
| Type | 3a | 3b | 3c | 3d | 3e | 3f | Function |
| 1 | x | x | | | | | conductor left/right |
| 2 | | x | | x | | | conductor |
| | | | | | | | “around the corner |
| 3 | x | x | | | x | x | Crossing in the plane |
| 4 | | | | x | x | x | Conductor front/rear |
| | | | | | | | with through contact |
| 5 | | | x | x | | | conductor top/bottom |
| 6 | x | x | x | x | x | x | Crossing all sides |
| 7 | . . . | | | | | | . . . |

The columns of Table 1 show the electrical connection areas 3a, 3b, 3c, 3d, 3e, 3f and the rows show possible types or specific examples of possible electrical connections between the electrical connection areas. The symbol x indicates that within this type there is a short circuit between the marked electrical connection areas. An empty field, on the other hand, indicates an open or non-existent contact between the electrical connection areas within this type. For example, in the case of the type 1 functional cell, only the first and second terminal regions 3a, 3b are shorted, resulting in a “linear” electrical conductor from left to right or from right to left. In the case of the functional cell of type 2, on the other hand, only the second and the fourth connection areas 3b, 3d are short-circuited, so that an electrical conductor results which connects the electrical connection areas via a corner, i.e. the electrical connection areas on two mutually perpendicular outer walls of the housing 2. By the symbol “ . . . ” in the case of type 7, it is intended to indicate that an electrical conductor can electrically connect the electrical connection areas or at least some of the electrical connection areas 3a, 3b, 3c, 3d, 3e, 3f to each other as desired. The examples shown in the table are accordingly not intended to be restrictive.

In addition to this, at least one further electrical conductor can electrically connect at least part of the remaining electrical connection areas that are not yet connected to each other.

FIGS. 7A and 7B show a front view and a top view of a further embodiment of a functional cell 1. In contrast to the functional cells shown so far, the functional cell 1 in FIGS. 7A and 7B has only a first and a second electrical connection area 3a, 3b. FIGS. 8A and 8B, on the other hand, show a front view and a top view of a functional cell 1 which, in contrast to the functional cells shown so far, has more than six electrical connection areas, in particular ten electrical connection areas. However, these two embodiment examples are not to be understood as restricting the number and positioning of electrical connection areas on the outer surfaces of the housing 2 of a functional cell 1. Rather, it is intended to make clear that any number of connection bays may be arranged on the outer surfaces of the housing 2 of a functional cell 1 as required.

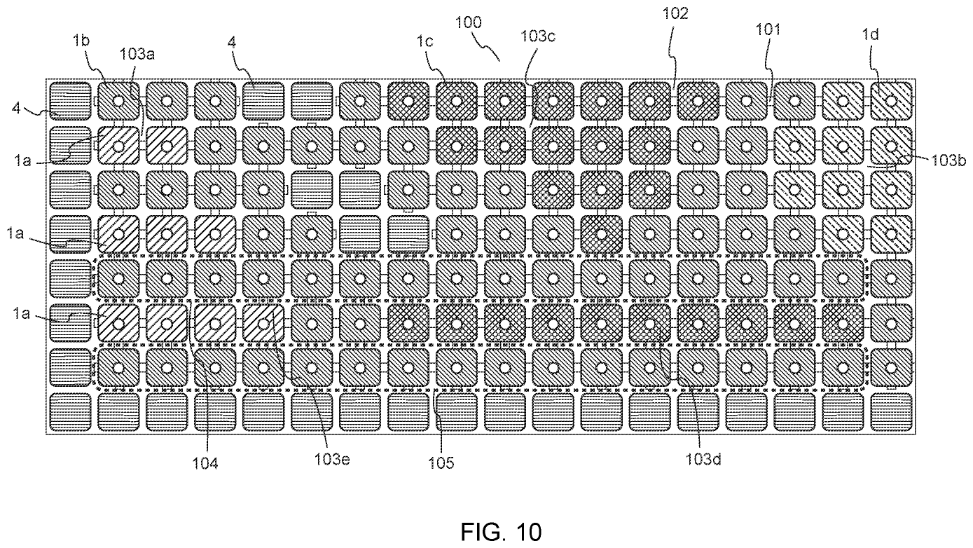

FIGS. 9A to 9H show various possible housing shapes of a functional cell 1. For example, the housing 2 can be formed in the shape of a cube according to FIG. 9A, or in the shape of a cube with rounded edges according to FIG. 9B, or in the shape of a cube with very strongly rounded edges or rounded edges according to FIGS. 9C and 9D. As shown in FIG. 9E, the housing 2 can also be formed in the shape of a sphere or approximately a sphere, or the housing can be formed in the shape of a truncated pyramid according to FIG. 9F.

For manufacturing reasons, it is also possible for the housing 2 to have undercuts or a multi-layered structure, similar to the cuboids arranged one on top of the other shown in FIGS. 9G and 9H. Such undercuts or steps may be formed, for example, by using lithography processes or stepwise etching processes to form step-like shapes in the manufacture of the housing.

However, the housing shapes shown are not intended to be restrictive; other shapes known to those skilled in the art can also be used for the housing.

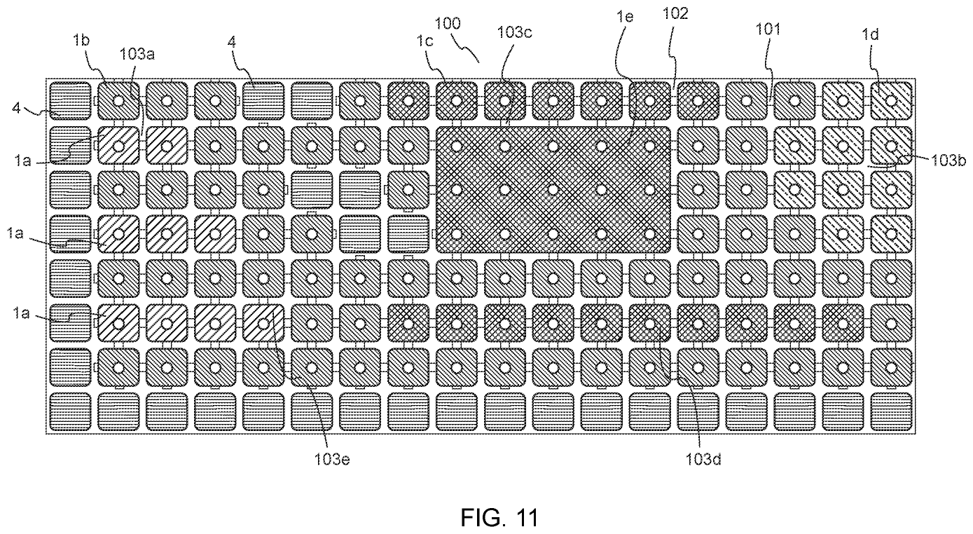

FIG. 10 shows an embodiment of a microsystem 100 comprising a plurality of functional cells 1a, 1b, 1c, 1d, and a plurality of non-electric cells 4 encapsulated in an interconnect layer or material 102. Adjacent functional cells 1a, 1b, 1c, 1d of different cell types are thereby in electrical connection 101 with each other. The plurality of functional cells 1a, 1b, 1c, 1d, as well as the plurality of non-electric cells 4 are characterized in particular by the fact that the housings of the individual cells have substantially the same dimensions, and the cells can thus be easily arranged or stacked next to and on top of each other in a desired order.

For example, such a microsystem 100 may form a microrobot or other autonomous microsystem.

The microsystem 100 has a plurality of subregions that perform different functions within the microsystem. The sub-regions are characterized by the fact that the cells therein have the same cell type, are arranged adjacent to each other, and are electrically connected to each other, at least in the case of the functional cells.

The non-electric cells 4 at the left and bottom edges of the microsystem 100 form, for example, an outer armor or skin for the microsystem 100. This makes it possible to protect the functional cells located inside the microsystem from external damage. The non-electric cells 4 inside the microsystem 100, on the other hand, can serve as spacers, for example.

For example, a first subset 103a of functional cells 1a, some of which are arranged adjacent to each other, has a cell type of an electric power generating cell. In particular, the functional cells 1a of the first subset 103a comprise a photocell or a solar cell as a functional element for converting ambient light incident on the microsystem 100 into electrical energy.

The microsystem further comprises a second subset 103b of functional cells formed by electrical energy storing cells 1d. The electrical energy storing cells 1d are arranged adjacent to each other and are in electrical communication with each other. In particular, the functional cells 1d of the second subset 103a include, as a functional element, an accumulator or a capacitor to store the electric energy generated by the electric energy generating cells 1a.

A third subset 103c is formed by electrical energy consuming cells 1c. Together, the functional cells 1c of the third subset form a controller for the microsystem. For this purpose, the functional cells 1c of the third subset 103a may include, in particular, artificial neurons or integrated circuits as a functional element.

Further, the microsystem has a fourth subset 103d of functional cells formed by electrical energy consuming cells 1c. The functional cells of the fourth subset are also arranged adjacent to each other. The electrical energy consuming cells 1c of the fourth subset 103d may comprise, for example, uLEDs or actuators as a functional element, such that the cells of the fourth subset 103d are adapted to emit light or enable movement of the microsystem, for example.

The functional cells of the first, second, third, and fourth subsets are interconnected via a fifth subset 103e of electrical energy conducting cells 1b. Through the electrical energy conducting cells 1b, it is possible to supply all cells with the required energy and thus enable interaction between the individual functional cells or subsets.

For example, the electrical energy conducting cells 1b may pro-vide negative 104 and positive 105 voltage supplies to the fourth subset 103d of electrical energy consuming cells 1c to supply power to the electrical energy consuming cells 1c of the fourth subset 1d. The electrical energy consuming cells 1c of the fourth subset 1d may further include, for example, a switching input for activating and deactivating the cells, which is connected to the electrical energy consuming cells 1c of the third subset 103c via electrical energy conducting cells 1b.

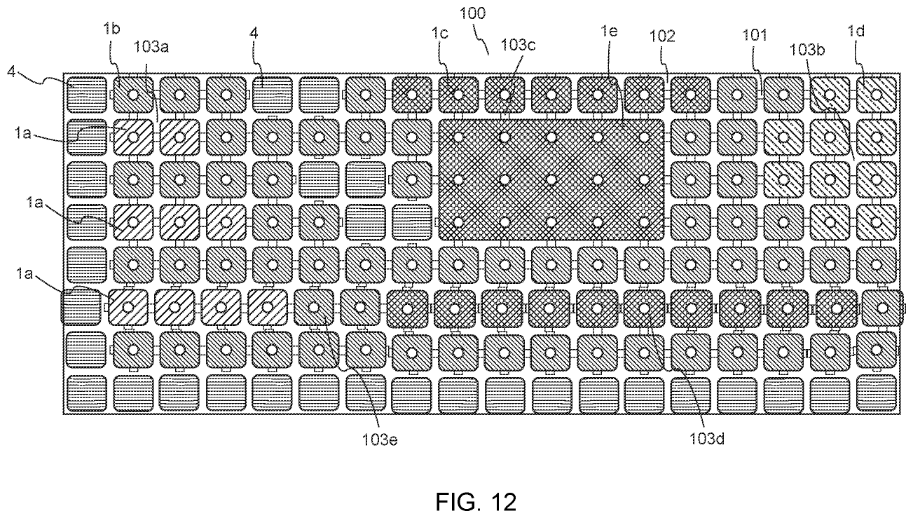

FIG. 11 shows another embodiment of a microsystem 100. In addition to the microsystem 100 shown in FIG. 10, the third subset 103c of electrical energy consuming cells 1c that together form a controller for the microsystem includes another electrical energy consuming cell 1e. In particular, the further electrical energy consuming cell 1e is characterized by having dimensions that are substantially a multiple, of the dimensions of a housing of one of the other electrical energy consuming cells 1c used in the microsystem. In the example shown, the further electrical energy consuming cell 1e has dimensions corresponding to fifteen times the dimensions of one of the other electrical energy consuming cells 1c used in the microsystem. Thus, within the microsystem 100, the further electrical energy consuming cell 1e replaces fifteen of the other electrical energy consuming cells 1c used in the microsystem in terms of volume. However, in terms of basic structure, the further electrical energy consuming cell 1e corresponds to the other electrical energy consuming cells 1c used in the microsystem, differing only in size.

By having larger dimensions of the further electrical energy consuming cell 1e or the housing of the further electrical energy consuming cell 1e, a larger integrated circuit (IC) can be arranged in the cell. This may, for example, increase the computing power of the microsystem 100 because, unlike multiple small integrated circuits in multiple smaller functional cells, a larger integrated circuit (IC) in a larger cell may have greater computing power.

In the case of FIG. 11, the fourth subset 103d of electric energy consuming cells 1c comprises actuators, for example in the form of a heating wire inside the housing of the cell, and a liquid, in particular oil, surrounding the heating wire and placed in the housing as a functional element. When the electrical energy consuming cells 1c are energized, the heating wire heats up and thus the oil surrounding the heating wire heats up. This causes the housing of the cells to expand, so that the electrical energy consuming cells 1c shift slightly in comparison to the neighboring cells. This displacement results in a movement in the microsystem 100.

Such a situation when the electric energy consuming cells 1c of the fourth subset 103d are heated and thus expanded is shown in FIG. 12. Therein, it can be seen that the row in which the electric energy consuming cells 1c of the fourth subset 103d are arranged have slightly expanded and slightly shifted com-pared to the other cells of the microsystem. Thus, by selectively introducing and heating such actuator cells, a desired movement within the microsystem 100 can be achieved.

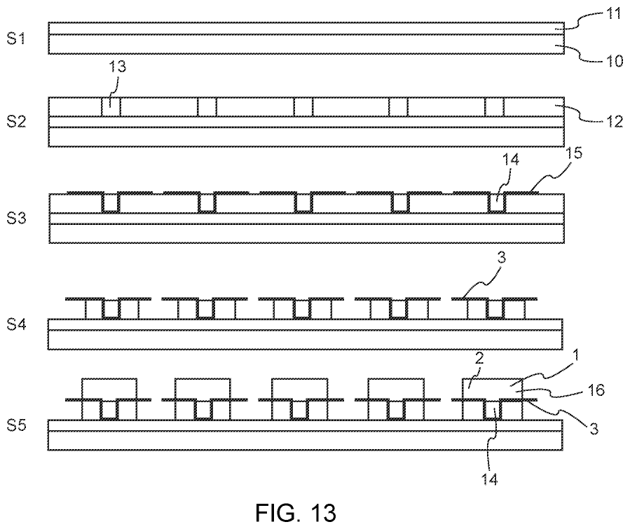

FIG. 13 shows steps of a method for manufacturing a functional cell, in particular for manufacturing a functional cell according to some of the aspects already mentioned. In a first step S1, the method comprises providing a temporary carrier 10 having a release layer 11 disposed thereon. The temporary carrier 10 may, for example, be formed by a transparent material such as glass. The release layer 11, on the other hand, can be formed by a material which can be applied very thinly, in particular with a thickness in the range of 50 nm to 200 nm, and which can be dissolved under the action of light or a wet chemical process.

In a further step S2, a base layer 12 is applied to the release layer and this is structured so that several cavities 13 are formed in the release layer. Processes from thin-film technology or thin-film technology, such as physical vapor deposition processes (PVD), chemical vapor deposition processes (CVD), lithography processes, and etching techniques, can be used for this. Furthermore, processes known from printing technology can also be used, such as stereo lithography, jet printing, screen printing, stencil printing, and offset printing.

In a step S3, a functional element 14 is arranged in each of the cavities, which is assigned to a cell type and by which the cell type of the resulting functional cells can be identified. In the case shown, the functional element 14 is an electrical conductor, so that the cell is of the cell type of an electrical energy conducting cell. In addition thereto, an electrically conductive structure 15 is applied to the base layer 12 and adjacent to the functional element 14. The electrically conductive structure 15 is applied such that the electrical connection areas of the functional cell are formed on the base layer. In particular, the application of an electrically conductive structure 15 can be performed, for example, by means of vapor deposition and sputtering of an electrically conductive material and subsequent lift-off processes or etching techniques.

In a step S4, the base layer 12 is then structured and areas of the base layer between the individual functional cells are removed so that they are formed individually on the release layer 11. By structuring the base layer 12, areas of the electrically conductive structure 15 are additionally exposed so that they protrude beyond the material of the base layer and form the electrical connection areas 3 in the later final product.

In a step S5, a cover layer 16 is applied to the base layer 12 or the electrically conductive structure 15 to enclose the functional element 14. The application of the cover layer can again be carried out by means of processes from thin-film technology or thin-film technology or by means of processes known from printing technology.

The cover layer 16 can be applied in particular in such a way that it laterally terminates with the outer edges of the structured base layer 12. Together, the base layer 12 and the cover layer 16 form the housing 2 of the functional cells 1, in the interior of which a functional element 14 is arranged and on the outer surfaces of which the electrical connection areas 3 are arranged.

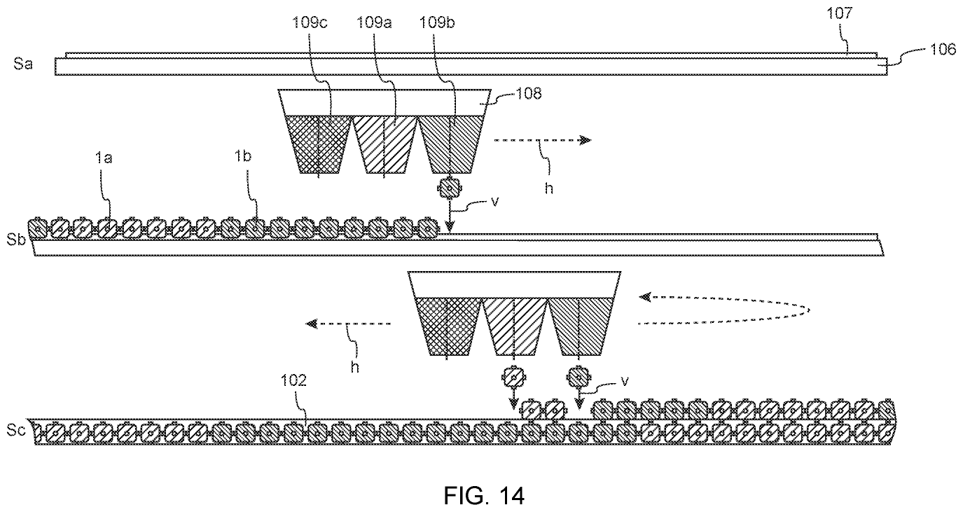

FIG. 14 shows steps of a method for manufacturing a microsystem comprising a plurality of functional cells, in particular for manufacturing a microsystem comprising a plurality of functional cells according to some of the aspects already mentioned. In a first step Sa, the method comprises providing a further temporary carrier 106 having an adhesive layer 107 disposed thereon. The further temporary carrier 106 may, for example, be formed by a transparent material such as glass, which may be removed from the microsystem after completion thereof. The adhesive layer 107, on the other hand, may be formed by a material that substantially corresponds to the material of the interconnect layer according to some of the aspects already mentioned, or may be a component of the interconnect layer.

In a step Sb, a subcarrier structure 108 is arranged at a defined distance above the adhesive layer 107, the subcarrier structure 108 comprising a plurality of regions 109a, 109b, 109c. The regions 109a, 109b, 109c are each populated with functional cells of different cell types. For example, a first region 109a is populated with electrical energy generating cells 1a, a second region 109b is populated with electrical energy conducting cells 1b, and a third region 109c is populated with electrical energy consuming cells 1c. However, the subcarrier structure 108 may include more than the three regions shown in the figure, and thus may be populated with a greater variety of different types and designs of functional cells.

For example, the subcarrier structure may be in the form of a subcarrier on which the functional elements are arranged in different areas. However, the subcarrier structure may also be in the form of a feeder and the different areas may be in the form of individual subcarriers or rollers on which the functional cells are arranged.

The subcarrier structure 108 is arranged above the adhesive layer 107 and can be moved parallel to the adhesive layer 107 in the horizontal direction h. At the same time, the functional cells 1a, 1b, 1c are irradiated with light in a desired sequence so that they detach from the subcarrier structure 108 and fall onto the adhesive layer 107 in the vertical direction v. By moving the subcarrier structure along the horizontal direction h and irradiating the functional cells on the regions of the subcarrier structure 108 selectively, the functional cells can be arranged in a desired range order side by side in a layer on the adhesive layer 107. By irradiating the functional cells, they experience an impulse and fall in the vertical direction v onto the adhesive layer 107, on which they adhere to the desired position or sink into the material of the adhesive layer 107. Likewise, it is possible that not only individual functional cells are irradiated and detached, but also several functional cells can be irradiated simultaneously, so that several functional cells can be placed on the adhesive layer at the same time. Individual process steps can be carried out in a similar way to a LIFT process (Laser Induced Forward Transfer) or inkjet printing process, for example.

To create a further layer with functional cells on the resulting layer, the functional cells are encapsulated in a interconnect layer 102. In particular, the interconnect layer 102 can comprise the same material as the adhesive layer 107.

In a further step Sc, the subcarrier structure 108 is arranged at a defined distance above the first layer of functional cells and can now be moved in the horizontal direction h parallel to the adhesive layer 107 or the first layer of functional cells. At the same time, the functional cells 1a, 1b, 1c are irradiated with light in a desired sequence so that they detach from the subcarrier structure 108 and fall onto the first layer of functional cells or onto the interconnect layer 102 in the vertical direction v. By moving the subcarrier structure along the horizontal direction h and selectively irradiating the functional cells on the regions of the subcarrier structure 108, the functional cells can be arranged in a desired range sequence side by side in another layer on the first layer of functional cells or on the interconnect layer 102.

The first and second layers can comprise a different sequence of functional cells arranged next to each other and a different number of functional cells. By creating multiple layers, any shape can be created that the final microsystem will have.

### REFERENCE LIST

1 functional cell
1a electric energy generating cell
1b electric energy conducting cell
1c electric energy consuming cell
1d electric energy storing cell
1e further functional cell
2 housing
3 electrical connection area
3a first electrical connection area
3b second electrical connection area
3c third electrical connection area
3d fourth electrical connection area 3d
3e fifth electrical connection area
3f sixth electrical connection area
4 non-electric cell
5 housing
6 coating
7 solder bump
8 contact pad
9 solder wetting area
10 temporary carrier
11 release layer
12 base layer
13 cavity
14 functional element
15 electrically conductive structure
16 cover layer
100 microsystem
101 electrical connection
102 interconnect layer
103a first subset
103b second subset
103c third subset
103d fourth subset
103e fifth subset
104 negative voltage supply
105 positive voltage supply
106 further temporary carrier
107 adhesive layer
108 subcarrier structure
109a first area
109b second area
109c third area
b width
h horizontal direction
V vertical direction

1-34. (canceled)

35. A microsystem comprising a plurality of functional cells with at least one functional cell of a first cell type and at least one functional cell of a second cell type different to the first cell type, wherein the plurality of functional cells is at least partially electrically coupled to each other, wherein each functional cell is formed by one of the following cell types:
an electrical energy generating cell;
an electrical energy storing cell;
an electrical energy conducting cell; and
an electrical energy consuming cell;
wherein each functional cell comprises:
a housing of an electrically insulating material, the housings of each two functional cells of a different cell type having the same dimensions;
at least one first electrical connection area and at least one second electrical connection area; and
a functional element arranged inside the housing with electrical connection of the at least one first electrical connection area and the at least one second electrical connection area.

36. The microsystem according to claim 35, wherein the plurality of functional cells are arranged adjacent to each other in a first plane.

37. The microsystem according to claim 35, wherein a first subset of the plurality of functional cells are arranged adjacent to each other in a first plane, and a second subset of the plurality of functional cells are arranged in a second plane parallel to the first plane.

38. The microsystem according to claim 35, further comprising at least one non-electric cell, wherein a housing of the at least one non-electric cell has substantially the same dimensions as the housing of a functional cell.

39. The microsystem according to claim 38, wherein the housing of the at least one non-electric cell is formed by a substantially transparent material.

40. The microsystem according to claim 35, wherein the functional cells and the non-electric cells are molded in an interconnect layer.

41. The microsystem according to claim 40, wherein the interconnect layer is formed of an electrically insulating material, in particular one of the following materials:
a synthetically produced hydrocarbon;
plastic;
silicone;
acrylic;
epoxy resin;
PET;
PE;
a thermoplastic;
a thermoset; and
an elastomer.

42. The microsystem according to claim 35, wherein a subset of the plurality of functional adjacent cells have the same cell type.

43. The microsystem according to claim 35, wherein the at least one first electrical connection area and the at least one second electrical connection area of each functional cell is formed by a leaf spring projecting from the housing of the respective functional cell, and the opposing leaf springs of two adjacent functional cells are in electrically conductive connection.

44. The microsystem according to claim 35, wherein the at least one first electrical connection area and the at least one second electrical connection area of each functional cell is formed with solder bumps, and the opposing solder bumps of two adjacent functional cells are soldered together.

45. The microsystem according to claim 35, further comprising another functional cell whose housing has dimensions substantially equal to a multiple of the dimensions of a housing of one of the plurality of functional cells.

46. The microsystem according to claim 35, wherein the functional element of at least one of the plurality of functional cells comprises at least one of the following:
an electrical conductor in the case of the cell type being of an electrical energy conducting cell;
a photocell in the case of the cell type being of an electric energy generating cell;
a solar cell, in particular μ-solar cell, in the case of the cell type being of an electric energy generating cell;
a fuel cell, in particular a μ-fuel cell, in the case of the cell type being of an electrical energy generating cell;
a piezoelectric element in the case of the cell type being of an electric energy generating cell or in the case of the cell type being of an electric energy consuming cell;
an accumulator, in particular a μ-accumulator, in the case of the cell type being an electric energy storing cell;
a capacitor in the case of the cell type being an electric energy storing cell;
an optoelectronic semiconductor component, in particular an LED or μ-LED or a sensor or μ-sensor in the case of the cell type being of an electrical energy consuming cell;
an artificial neuron in the case of the cell type being of an electrical energy consuming cell;
an integrated circuit, in particular μ-IC, in the case of the cell type being of an electric energy consuming cell; and
a heating wire and optionally additionally a liquid, in particular oil, surrounding the heating wire and introduced into the housing, in the case of the cell type being of an electrical energy consuming cell.

47. The microsystem according to claim 35, wherein the functional element of at least one of the plurality of functional cells does not exceed a size of 100 μm×100 μm×100 μm.

48. The microsystem according to claim 35, wherein the at least one first electrical connection area and the at least one second electrical connection area of at least one of the plurality of functional cells are each formed by a leaf spring projecting from the housing.

49. The microsystem according to claim 48, wherein the leaf springs comprise a coating of gold or a solder compound.

50. The microsystem according to claim 35, wherein the at least one first electrical connection area and the at least one second electrical connection area of at least one of the plurality of functional cells each have a roughened or spiked surface outside the housing.

51. The microsystem according to claim 35, wherein the at least one first electrical connection area and the at least one second electrical connection area of at least one of the plurality of functional cells each comprise a solder bump arranged on the housing.

52. The microsystem according to claim 51, wherein a solder wetting area on the housing in the region of each solder bump is smaller than the solder bump arranged on the housing.

53. The microsystem according to claim 35, wherein the at least one of the plurality of functional cells comprises at least one third and at least one fourth electrical connection area, wherein the at least one third and the at least one fourth electrical connection area are arranged in particular on two opposite outer surfaces of the housing.

54. The microsystem according to claim 53, wherein the at least one of the plurality of functional cells comprises at least one fifth and at least one sixth electrical connection area, wherein the at least one fifth and the at least one sixth electrical connection area are arranged in particular on two opposite outer surfaces of the housing.

55. The microsystem according to claim 35, wherein at least one of the plurality of functional cell is of the cell type of an electric energy conducting cell, and the functional element comprises at least one electric conductor electrically connecting the at least one first and/or the at least one second and/or the at least one third and/or the at least one fourth and/or the at least one fifth and/or the at least one sixth electric connection area.

56. The microsystem according to claim 35, wherein at most one of the at least one first, second, third, fourth, fifth and sixth electrical connection areas is disposed on each outer surface of the housing of at least one of the plurality of functional cells.

57. The microsystem according to claim 35, wherein at least two of the at least one first, third and fifth or the at least one second, fourth and sixth electrical connection areas are arranged on at least one outer surface of the housing of at least one of the plurality of functional cells.

58. The microsystem according to claim 35, wherein the housing of at least one of the plurality of functional cells is rotationally symmetric along at least one axis or mirror symmetric along at least one plane.

59. The microsystem according to any claim 35, wherein the housing of at least one of the plurality of functional cells comprises one of the following forms:
a cube, especially a cube with rounded edges;
a cuboids, especially a cuboid with rounded edges;
a bar, especially a bar with rounded edges;
a sphere;
an ellipsoid;
a pyramid, especially a pyramid with rounded edges;
a truncated pyramid, in particular a truncated pyramid with rounded edges; and
a truncated cone, especially a truncated cone with rounded edges.

60. The microsystem according to claim 35, wherein the housing of at least one of the plurality of functional cells comprises any one of the following materials:
epoxy resin;
silicone;
acrylic;
PET;
PE;
a thermoplastic;
a thermoset;
Al₂O₃;
AlN;
glass; and
ceramics.

61. The microsystem according to claim 35, wherein at least one of the plurality of functional cells comprises an adhesive layer covering at least one outer surface of the housing.

62. The microsystem according to claim 35, wherein the at least one first electrical connection area and the at least one second electrical connection area of at least one of the plurality of functional cells are arranged in particular on two opposite outer surfaces of the housing.

63. A method for manufacturing a microsystem comprising a plurality of functional cells with at least one functional cell of a first cell type and at least one functional cell of a second cell type different to the first cell type, wherein the plurality of functional cells is at least partially electrically coupled to each other, wherein each functional cell is formed by one of the following cell types:
an electrical energy generating cell;
an electrical energy storing cell;
an electrical energy conducting cell; and
an electrical energy consuming cell;
comprising the steps:
providing a carrier with an adhesive layer thereon;
arranging a subcarrier structure above the adhesive layer, the subcarrier structure comprising a plurality of regions each populated with different cell types of the functional cells;
irradiating a first functional cell in a first region of the subcarrier structure such that the functional cell detaches and falls onto the adhesive layer; and
irradiating another functional cell in a second region of the subcarrier structure such that the functional cell detaches and falls onto the adhesive layer adjacent to the first cell.

64. The method according to claim 63, further comprising a step of molding the functional cells arranged on the carrier.

65. The method according to claim 63, further comprising a step of manufacturing a functional cell of a cell type, wherein the cell type forms a cell type consisting of the following types:
an electrical energy generating cell;
an electrical energy storing cell;
an electrical energy conducting cell;
an electrical energy consuming cell;
the step of manufacturing a functional cell comprising the steps:
providing a carrier having a release layer thereon;
providing a base layer on top of the release layer;
structuring the base layer to create at least one cavity or at least one hollow space;
arranging a functional element, which is associated with the respective cell type and/or identifies the cell type, in the at least one cavity or the at least one hollow space;
providing an electrically conductive structure to create at least a first electrical connection area and at least a second electrical connection area; and
providing a cover layer to enclose the functional element.

66. The method according to claim 65, wherein the functional element of at least one of the plurality of functional cells comprises at least one of the following:
an electrical conductor in the case of the cell type being of an electrical energy conducting cell;
a photocell in the case of the cell type being of an electric energy generating cell;
a solar cell, in particular μ-solar cell, in the case of the cell type being of an electric energy generating cell;
a fuel cell, in particular a μ-fuel cell, in the case of the cell type being of an electrical energy generating cell;
a piezoelectric element in the case of the cell type being of an electric energy generating cell or in the case of the cell type being of an electric energy consuming cell;
an accumulator, in particular a μ-accumulator, in the case of the cell type being an electric energy storing cell;
a capacitor in the case of the cell type being an electric energy storing cell;
an optoelectronic semiconductor component, in particular an LED or μ-LED or a sensor or μ-sensor in the case of the cell type being of an electrical energy consuming cell;
an artificial neuron in the case of the cell type being of an electrical energy consuming cell;
an integrated circuit, in particular μ-IC, in the case of the cell type being of an electric energy consuming cell; and
a heating wire and optionally additionally a liquid, in particular oil, surrounding the heating wire and introduced into the housing, in the case of the cell type being of an electrical energy consuming cell.

67. The method according to claim 65, wherein the step of manufacturing a functional cell further comprises a step of structuring the base layer and/or the cover layer and/or the electrically conductive structure by means of which a plurality of functional cells are separated from each other.

68. The method according to claim 65, wherein the step of providing an electrically conductive structure comprises:
creating an electrical connection area;
providing a solder stop around the connection area; and
providing a solder bump to the electrical connection area.
